(19) United States
(12) Patent Application Publication
(10) Pub. No.: US 2026/0128086 A1
(43) Pub. Date: May 7, 2026

(54) MEMORY AND OPERATION METHOD THEREOF, TRIM REGISTER, MEMORY SYSTEM

(71) Applicant: YANGTZE MEMORY TECHNOLOGIES CO., LTD., Wuhan (CN)

(72) Inventors: Simin ZHANG, Wuhan (CN); Xiaodong MEI, Wuhan (CN); HuangPeng ZHANG, Wuhan (CN); Xiang FU, Wuhan (CN); Chunyan HU, Wuhan (CN)

(21) Appl. No.: 19/176,817

(22) Filed: Apr. 11, 2025

(30) Foreign Application Priority Data
Nov. 7, 2024 (CN) 202411587929.9

(51) Int. Cl. G11C 11/4096; G11C 11/4076; G11C 11/4093

(52) U.S. Cl. CPC G11C 11/4096; G11C 11/4076; G11C 11/4093

(57) ABSTRACT

Examples of the present disclosure disclose a memory and an operation method thereof, a trim register, a memory system, and an electronic device. The memory includes: a pre-charge circuit configured to: pre-charge a read node based on a pre-charge signal; a trim register coupled to the read node and configured to: output trim information latched in the trim register based on a read enable signal; and select whether to discharge the read node based on the trim information; and a read output circuit coupled to the read node and configured to: generate a read output signal based on a read output enable signal and a level of the read node, wherein the read output signal is to indicate whether the trim information is correct.

### CROSS-REFERENCE TO RELATED APPLICATIONS

The present application claims priority to Chinese Patent Application No. 202411587929.9, which was filed Nov. 7, 2024, and is hereby incorporated herein by reference in its entirety.

### TECHNICAL FIELD

Examples of the present disclosure relate to the field of memory technology, including, but not limited to, a memory and an operation method thereof, a trim register, a memory system, and an electronic device.

### BACKGROUND

A memory is categorized as a volatile memory or a non-volatile memory based on whether stored data is retained in the event of a power failure, wherein a volatile memory with data loss in the event of a power failure may include a static random access memory (SRAM) and dynamic random access memory (DRAM).

After the memory has been manufactured, the impact of process deviations, layout errors, and the like on the memory may be adjusted through trimming test, thereby improving memory performance. For example, the memory may adjust its operation parameters by accessing trim information stored in a trim register.

### SUMMARY

According to a first aspect of the examples of the present disclosure, a memory is provided, comprising: a pre-charge circuit configured to: pre-charge a read node based on a pre-charge signal; a trim register coupled to the read node and configured to: output trim information latched in the trim register based on a read enable signal; and select whether to discharge the read node based on the trim information; and a read output circuit coupled to the read node and configured to: generate a read output signal based on a read output enable signal and a level of the read node, wherein the read output signal is to indicate whether the trim information is correct.

In some examples, the trim register comprises: a dynamic latch circuit configured to: latch the trim information; and an output circuit coupled to the dynamic latch circuit and configured to: output the trim information latched in the dynamic latch circuit based on the read enable signal; and discharge the read node in response to the trim information that is output being in a first state.

In some examples, the pre-charge circuit is configured to: pre-charge the read node to a first level based on the pre-charge signal; the output circuit is configured to: discharge the read node from the first level to a second level based on the trim information that is output being in the first state; and the read output circuit is configured to: generate a first read output signal based on the read node being at the second level and the read output enable signal, wherein the first read output signal is to indicate whether the trim information in the first state is correct.

In some examples, the output circuit is further configured to: maintain a level of the read node in response to the trim information that is output being in a second state, wherein the second state is different from the first state.

In some examples, the pre-charge circuit is configured to: pre-charge the read node to a first level based on the pre-charge signal; and the read output circuit is configured to: generate a second read output signal based on the read node being at the first level and the read output enable signal, wherein the second read output signal is to indicate whether the trim information in the second state is correct.

In some examples, the output circuit comprises a first transistor and a second transistor, and wherein, a first terminal of the first transistor is coupled to a first power terminal, a second terminal of the first transistor is coupled to a first terminal of the second transistor, and a control terminal of the first transistor is configured to receive the read enable signal; and a second terminal of the second transistor is coupled to the read node, and a control terminal of the second transistor is configured to receive the trim information.

In some examples, the trim register further comprises an address selection circuit comprising at least one third transistor, and wherein, a first terminal of the third transistor is coupled to the dynamic latch circuit, a second terminal of the third transistor is coupled to the first power terminal, and a control terminal of the third transistor is configured to receive an address signal; and the first terminal of the first transistor is coupled to the first power terminal through the third transistor.

In some examples, the trim register comprises a plurality of trim registers commonly coupled to the read node, and the memory further comprises: a latch circuit, wherein an input terminal of the latch circuit is coupled to the read output circuit, an output terminal of the latch circuit is coupled to a pin, and the latch circuit is configured to: latch read output data in the read output signal, wherein the read output data is to indicate whether the trim information latched in the corresponding trim register is correct.

In some examples, the memory further comprises: a control logic circuit coupled to the pre-charge circuit, the trim register, and the read output circuit respectively and configured to: generate the pre-charge signal at a first time instant; generate the read enable signal at a second time instant after the first time instant.

In some examples, the pre-charge circuit comprises a fourth transistor, and wherein a first terminal of the fourth transistor is coupled to the read node, a second terminal of the fourth transistor is coupled to a second power terminal, and a control terminal of the fourth transistor is configured to receive the pre-charge signal.

According to a second aspect of the examples of the present disclosure, an operation method for a memory is provided, comprising: pre-charging a read node based on a pre-charge signal; outputting trim information latched in a trim register based on a read enable signal; discharging the read node in response to the trim information that is output being in a first state, wherein the trim register is coupled to the read node; and generating a first read output signal based on the read node being discharged to a second level and a read output enable signal, wherein the first read output signal is to indicate whether the trim information in the first state is correct.

In some examples, pre-charging a read node based on a pre-charge signal comprises: pre-charging the read node to a first level based on the pre-charge signal, wherein the first level is greater than the second level; and discharging the read node in response to the trim information that is output being in a first state comprises: discharging the read node from the first level to the second level in response to the trim information that is output being in the first state.

In some examples, the operation method further comprises: maintaining the read node at a first level in response to the trim information that is output being in a second state, wherein the second state is different from the first state, and the first level is greater than the second level.

In some examples, the operation method further comprises: generating a second read output signal based on the read node being at the first level and the read output enable signal, wherein the second read output signal is to indicate whether the trim information in the second state is correct.

In some examples, pre-charging a read node based on a pre-charge signal comprises: pre-charging the read node to the first level based on the pre-charge signal.

In some examples, the trim register comprises a plurality of trim registers commonly coupled to the read node, and the operation method further comprises: latching read output data in the first read output signal or the second read output signal, wherein the read output data is to indicate whether the trim information latched in the corresponding trim register is correct, respectively.

According to a third aspect of the examples of the present disclosure, a trim register is provided, comprising: a dynamic latch circuit configured to: latch trim information; and an output circuit coupled to the dynamic latch circuit and configured to: output the trim information latched in the dynamic latch circuit based on a read enable signal; and discharge a read node from a first level to a second level in response to the trim information that is output being in a first state.

In some examples, the output circuit is further configured to: maintain the read node at the first level in response to the trim information that is output being in a second state.

In some examples, the output circuit comprises a first transistor and a second transistor, and wherein, a first terminal of the first transistor is coupled to a first power terminal, a second terminal of the first transistor is coupled to a first terminal of the second transistor, and a control terminal of the first transistor is configured to receive the read enable signal; and a second terminal of the second transistor is coupled to the read node, and a control terminal of the second transistor is configured to receive the trim information.

In some examples, the trim register further comprises: an address selection circuit comprising at least one third transistor, wherein a first terminal of the third transistor is coupled to the dynamic latch circuit, and a second terminal of the third transistor is coupled to the first power terminal, a control terminal of the third transistor is configured to receive an address signal, and the first terminal of the first transistor is coupled to the first power terminal through the third transistor.

According to a fourth aspect of the examples of the present disclosure, a memory system is provided, comprising:
one or more memories as described in any example in the first aspect of the examples of the present disclosure;
a memory controller coupled to the memories and configured to control the memories.

According to a fifth aspect of the disclosed examples, an electronic device is provided, comprising a memory system as described in the fourth aspect of the examples of the present disclosure.

In the examples of the present disclosure, a memory comprises: a pre-charge circuit, a trim register, and a read output circuit. The pre-charge circuit is configured to pre-charge a read node based on a pre-charge signal. The trim register is coupled to the read node and is configured to: output trim information latched in the trim register based on a read enable signal; and select whether to discharge the read node based on the trim information. The read output circuit is coupled to the read node and is configured to: generate a read output signal based on a read output enable signal and a level of the read node A, wherein the read output signal is to indicate whether the trim information is correct. In this way, the readability of the trim information can be realized, thus users or testers may check whether the trim information is correct based on the read output signal RD_OUT.

### BRIEF DESCRIPTION OF THE DRAWINGS

In the figures, unless otherwise specified, the same reference numbers throughout multiple figures represent the same or similar components or elements. These figures may not be drawn to scale. It should be understood that these figures only depict some examples disclosed in the present application and should not be construed as limiting the scope of the present application.

FIG. 1 is a schematic diagram of a distribution of a memory provided by an example.

FIG. 2 is a schematic diagram of a memory provided by an example.

FIG. 3 is a schematic diagram of a trim register provided by an example.

FIG. 4 is a schematic diagram of a memory provided by examples of the present disclosure.

FIG. 5 is a schematic diagram of a trim register provided by examples of the present disclosure.

FIG. 6 is a schematic diagram of another memory provided by examples of the present disclosure.

FIG. 7 is a flowchart of an operation method for a memory provided by examples of the present disclosure.

FIG. 8 is a flowchart for reading out trim information provided by examples of the present disclosure.

FIG. 9 is an operation timing diagram of a memory provided by examples of the present disclosure.

FIG. 10 is a schematic diagram of an electronic device provided by examples of the present disclosure.

### DETAILED DESCRIPTION

In order to facilitate understanding of the present disclosure, examples of the present disclosure will be described in more detail below with reference to the accompanying drawings. Although examples of the present disclosure are shown in the drawings, it should be understood that the present disclosure may be implemented in various ways and should not be limited to the DETAILED DESCRIPTION set forth herein. Rather, these examples are provided so that the present disclosure can be more thoroughly understood and the scope of the present disclosure can be fully conveyed to those skilled in the art.

In the following description, numerous specific details are given in order to provide a more thorough understanding of the present disclosure. It will be apparent, however, to one skilled in the art that the present disclosure may be practiced without one or more of these details. In other examples, some technical features well-known in the art are not described to avoid confusion with the present disclosure; for example, not all features of the actual example are described here, and well-known functions and structures are not described in detail.

Generally, terminology may be understood at least partially from its usage in context. For example, depending at least in part on the context, the term “one or more” as used herein may be used to describe any feature, structure, or characteristic in a singular sense, or may be used to describe a combination of features, structures, or characteristics in a plural sense. Similarly, terms such as “one” or “said” may also be understood as conveying singular or plural usage, depending at least in part on the context. Additionally, the term “based” may be understood as not intended to convey an exclusive set of factors, and may alternatively allow for additional factors that are not explicitly described, also depending at least in part on the context.

Unless otherwise defined, the terms used herein are only for the purpose of describing specific examples and are not intended to be limiting of the present disclosure. When used herein, “a”, “an”, and “said/the ” in singular forms are also intended to include the plural form, unless the context clearly indicates otherwise. It should also be understood that at least one of the terms “including” or “comprising”, when used in the present specification, identify the presence of at least one of the described features, integers, operations, elements or components, but do not exclude the presence or addition of at least one of one or more other features, integers, operations, elements, components or groups. When used herein, the term “at least one of . . . ” includes any and all combinations of the relevant listed items.

In order to fully understand the present disclosure, detailed operations and structures will be presented in the following description to illustrate the technical solution of the present disclosure. The examples of the present disclosure are described in detail below, however, the present disclosure may also have other examples in addition to these detailed descriptions.

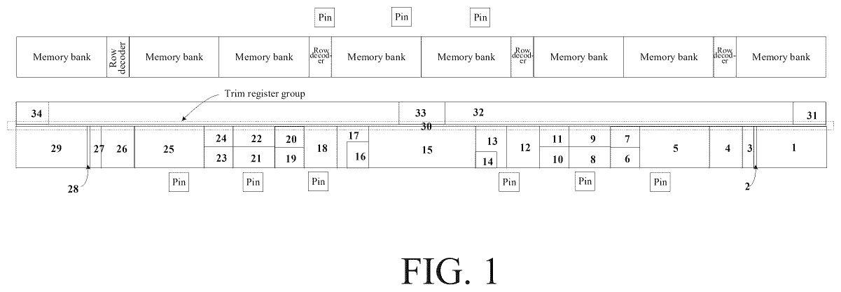

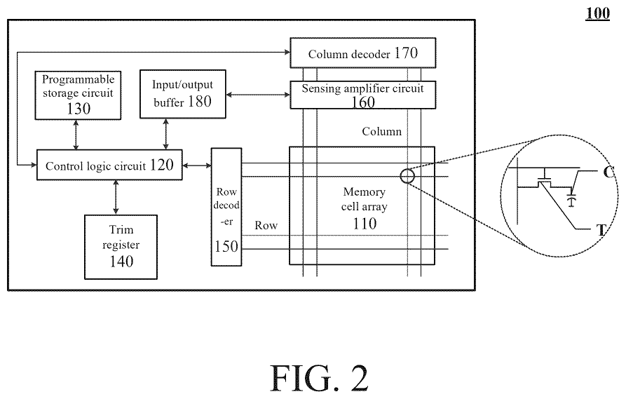

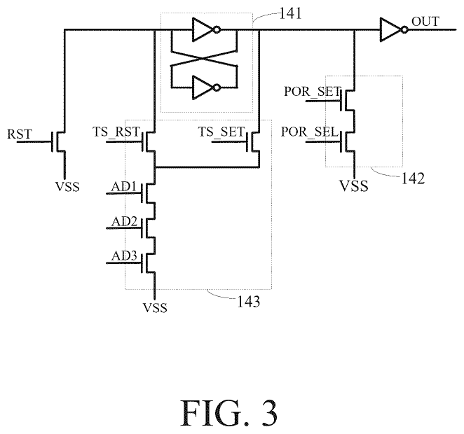

The trim information obtained after the memory trim test may be written into the memory and loaded into the corresponding trim register when the memory is powered on. FIG. 1 is a schematic diagram of a distribution of a memory provided by an example, FIG. 2 is a schematic diagram of a memory provided by an example, and FIG. 3 is a schematic diagram of a trim register provided by an example. Illustrations will be provided below in connection with FIGS. 1-3. Memory includes but is not limited to DRAM. For ease of understanding, DRAM is taken as an example for illustration.

Configuration information and trim information related to DRAM operations are stored in a non-volatile memory to enable normal and test operations, and therefore this information is substantial. This information will be loaded into quickly accessible trim registers during a power on initialization period. Referring to FIG. 1, the dashed box 30 represents an arrangement position of a trim register group, which includes a plurality of trim registers. It should be noted that numbers 1 to 34 in FIG. 1 are used to represent the arrangement positions of various functional circuits in DRAM, and specific functional circuits are not shown for simplicity. For example, numbers 1 and 29 may represent the arrangement position of a non-volatile memory for storing the configuration information and trim information.

Referring to FIG. 2, the memory 100 includes a memory cell array 110, which includes a plurality of memory cells arranged in an array. Each memory cell includes a transistor T and a capacitor C. The main principle of the memory cell is to use the amount of charge stored in the capacitor to represent whether a binary bit is 1 or 0.

The memory cell array 110 may be divided into a plurality of memory banks, wherein each memory bank comprises a plurality of memory blocks, and each memory block comprises a plurality of memory cell rows and a plurality of memory cell columns. Each memory cell row is coupled to a corresponding word line, and each memory cell column is coupled to a corresponding bit line. The memory cell array 110 specifies addresses using rows and columns to. By specifying the intersection of the row and the column (by specifying the row address and column address of DRAM), a memory controller may access each memory cell independently and perform read, write, or refresh operations on the data stored therein.

Referring still to FIG. 2, the memory 100 also includes peripheral circuits coupled to the memory cell array 110. The peripheral circuits may write data to or read data from the memory cell array 110 in response to a command (CMD) and an address (ADDR) received from the memory controller, or may provide control signals to a row decoder 150 and column decoder 170 for refreshing the memory cells included in the memory cell array 110. In other words, the peripheral circuits may perform all operations to process the data in the memory cell array 110. The peripheral circuits may comprise: control circuits corresponding to each memory block, such as a sensing amplifier circuit 160 and a word line drive circuit (not shown in the figure); control circuits corresponding to each memory bank, such as the row decoder 150, the column decoder 170 and the like; and control circuits corresponding to all memory banks, such as an input/output buffer 180, a command buffer, a command decoder, an address buffer, a mode register, etc.

The peripheral circuits also include a programmable storage circuit 130 and a trim register 140. The programmable storage circuit 130 is configured to store a plurality of trim information, which may be written into the programmable storage circuit 130 after the trim test and loaded into the trim register 140 during the power on initialization of the memory 100. The programmable storage circuit 130 includes at least one of non-volatile memories such as a One Time Programmable (OTP) memory, a Multi Time Programmable (MTP) memory, etc. The OTP memory may include a fuse array or an anti-fuse array, etc. As the programmable storage circuit 130 is a non-volatile memory, the loss of trim information can be avoided.

The trim register 140 needs to achieve the following three functions: 1) Data Latch, in which the trim information needs to be latched at a stable level; 2) Power On Reset (POR), in which data is loaded from a non-volatile memory upon power on, and this function does not require the trim register to be addressable; 3) test mode, in which test trim information input externally is loaded from a control logic circuit 120, and this function requires the trim register to be addressable to select the desired trim register, for example, to select a certain one of the plurality of trim registers.

Referring to FIG. 3, the trim register 140 includes a dynamic latch circuit 141, an initialization circuit 142, and an address selection circuit 143. The dynamic latch circuit 141 is configured to latch trim information to enable the data latch function. The initialization circuit 142 is configured to initialize the dynamic latch circuit to enable the POR function. The address selection circuit 143 is configured for addressing to enable the test mode function. However, the trim register 140 is not readable, and it cannot be ensured that the trim information written or loaded into the trim register is correct or to check that trim information, resulting in the function of the memory being affected.

Based on one or more of the technical issues mentioned above, a memory is provided by the examples of the present disclosure which may comprise a Random Access Memory (RAM), such as DRAM, Synchronous DRAM (SDRAM), SRAM, Double Data Rate SDRAM (DDR SDRAM), DDR2 SDRAM, DDR3 SDRAM, Phase Change RAM (PRAM), Magnetic RAM (MRAM), Resistive RAM (RRAM), etc. The following only takes DRAM as an example for illustration.

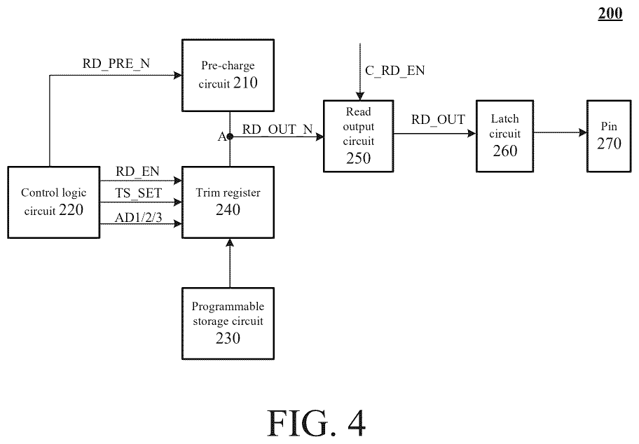

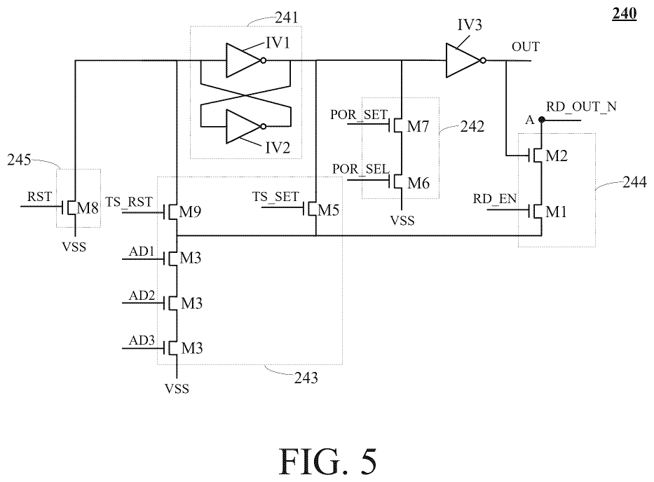

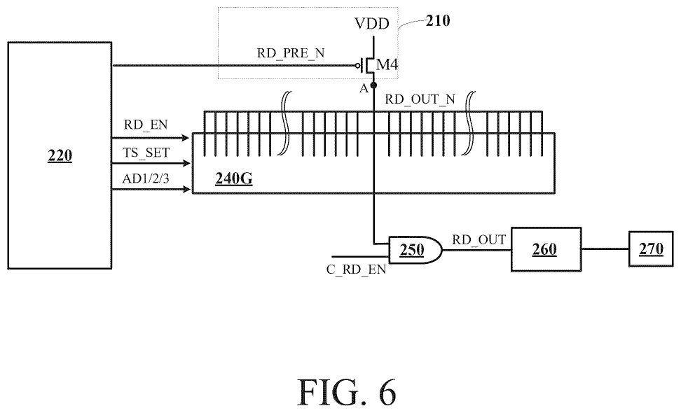

FIG. 4 is a schematic diagram of a memory provided by examples of the present disclosure, FIG. 5 is a schematic diagram of a trim register provided by examples of the present disclosure, and FIG. 6 is a schematic diagram of another memory provided by examples of the present disclosure. The memory provided by examples of the present disclosure is illustrated below in connection with FIGS. 4 to 6.

Referring to FIG. 4, the memory 200 includes a memory cell array and peripheral circuits coupled to the memory cell array. For the memory cell array, please refer to the description in connection with FIG. 2. The peripheral circuits include a pre-charge circuit 210, a control logic circuit 220, a programmable storage circuit 230, a trim register 240, a read output circuit 250, a latch circuit 260, and a pin 270. Of course, the peripheral circuits may also include other circuits not shown in FIG. 4.

In some examples, as shown with reference to FIG. 4, the pre-charge circuit 210 is configured to pre-charge a read node A based on a pre-charge signal RD_PRE_N; The trim register 240 is coupled to the read node A and is configured to: output trim information latched in the trim register 240 based on a read enable signal RD_EN; and select whether to discharge the read node A based on the trim information. The read output circuit 250 is coupled to the read node A and is configured to: generate a read output signal RD_OUT based on a read output enable signal C_RD_EN and a level RD_OUT_N of the read node A, wherein the read output signal RD_OUT is to indicate whether the trim information is correct.

In an example of the present disclosure, the pre-charge circuit 210 may pre-charge the read node A upon receiving the pre-charge signal RD_PRE_N until the read node A is charged to a certain level (e.g., a power level VDD in the following). The trim register 240 may output the latched trim information upon receiving the read enable signal RD_EN. The trim information that is output may cause the read node A to discharge from the certain level to another level (such as a ground level VSS in the following) or maintain the level of the read node A unchanged. The read output circuit 250 may generate the read output signal RD_OUT based on the level RD_OUT_N of the read node A upon receiving the read output enable signal C_RD_EN. The read output signal RD_OUT may be output from the pin 270 of the memory 200, and the read output signal RD_OUT is the reading result for the trim information latched in the trim register 240, thereby achieving the readability of the trim information. Users or testers may check whether the trim information is correct based on the read output signal RD_OUT. It should be noted that, the read node A may comprise any node on a signal transmission path between the trim register 240 and the read output circuit 250, as long as it is ensured that the pre-charge circuit 210 is coupled to the read node A. The examples of the present disclosure do not have any special limitation on the location of the read node A.

In some examples, as shown with reference to FIG. 5, the trim register 240 includes a dynamic latch circuit 241 and an output circuit 244 coupled to the dynamic latch circuit 241. The dynamic latch circuit 241 is configured to latch the trim information. The output circuit 244 is configured to: output the trim information latched in the dynamic latch circuit 241 based on the read enable signal RD_EN; and discharge the read node A in response to the trim information that is output being in a first state. Alternatively, the output circuit 244 is configured to maintain a level of the read node A in response to the trim information that is output being in a second state, wherein the second state is different from the first state.

In an example of the present disclosure, the trim register 240 may load the trim information from the programmable storage circuit 230 shown in FIG. 4 when the memory 200 enters an operation mode, and latch the loaded trim information to the dynamic latch circuit 241 (e.g., dynamic latch). The output circuit 244 may output the trim information latched in the dynamic latch circuit 241 upon receiving the read enable signal RD-EN. If the level signal corresponding to the trim information is high, the read node A can be caused to discharge, and the read output circuit 250 outputs the corresponding read output signal (e.g., RD_OUT=1) based on the level of the discharged read node A. On the contrary, if the level signal corresponding to the trim information is low, the level of the read node A can be caused to remain unchanged, and the read output circuit 250 outputs the corresponding read output signal (e.g., RD_OUT=0) based on the level of the read node A. In this way, the readability of the trim information latched in the trim register 240 can be achieved, so as to check whether the trim information is correct. In practical applications, the trim information may be represented by binary symbols “1” or “0”, wherein the binary symbol “1” indicates that the trim information is in a first state, and the corresponding level signal is at a high level; and the binary symbol “0” indicates that the trim information is in a second state, and the corresponding level signal is at a low level.

It should be noted that the trim register 240 in the memory 200 may comprise one or more trim registers, depending on the design of the memory 200 in practical applications. The examples of the present disclosure do not have any special limitation on the number of trim registers 240. The above-mentioned operation mode may comprise the mode that a chip enters normally after power on during actual use, while the test mode in the following may be accessing the internal programs of the chip through an interface before chip packaging, for example, in the test mode, the internal programs or parameters of the chip may be modified or debugged.

Dynamic latches are typically composed of two inverters to enable fast access to the trim information. For example, as shown with reference to FIG. 5, the dynamic latch circuit 241 includes a first inverter IV1 and a second inverter IV2. An output terminal of the first inverter IV1 is coupled to an input terminal of the second inverter IV2, and an output terminal of the second inverter IV2 is coupled to an input terminal of the first inverter IV1. Due to the small area of the dynamic latch, the circuit structure of the trim register 240 may be optimized and the area of the trim register 240 may be reduced, which is beneficial for miniaturization of the size of the memory 200.

The output circuit 244 may be composed of at least two transistors to enable the readability of the trim information. For example, as shown with reference to FIG. 5, the output circuit 244 includes a first transistor M1 and a second transistor M2, wherein a first terminal of the first transistor M1 is coupled to a first power terminal, a second terminal of the first transistor M1 is coupled to a first terminal of the second transistor M2, and a control terminal of the first transistor M1 is configured to receive the read enable signal RD_EN. A second terminal of the second transistor M2 is coupled to the read node A, and a control terminal of the second transistor M2 is configured to receive trim information. The first transistor M1 and the second transistor M2 include, but not limited to, NMOS transistors, and the first power terminal includes, but not limited to, a ground terminal. In the examples of the present disclosure, an example will be illustrated in which both the first transistor M1 and the second transistor M2 are NMOS transistors, and the first power terminal is the ground terminal.

In some examples, the pre-charge circuit 210 is configured to pre-charge a read node A to a first level based on a pre-charge signal RD_PRE_N. The output circuit 244 is configured to discharge the read node A from the first level to a second level based on the trim information that is output being in the first state. The read output circuit 250 is configured to generate a first read output signal based on the read node being at the second level and the read output enable signal C_RD_EN, wherein the first read output signal is to indicate whether the trim information in the first state is correct.

The pre-charge circuit 210 may be composed of at least one transistor to enable the pre-charging function. For example, as shown with reference to FIG. 6, the pre-charge circuit 210 includes a fourth transistor M4, wherein a first terminal of the fourth transistor M4 is coupled to the read node A, a second terminal of the fourth transistor M4 is coupled to a second power terminal, and a control terminal of the fourth transistor M4 is configured to receive the pre-charge signal RD_PRE_N. The fourth transistor M4 includes, but not limited to, a PMOS transistor, and the second power terminal includes, but not limited to, a power terminal. In the examples of the present disclosure, an example will be illustrated in which the fourth transistor M4 is the PMOS transistor and the second power terminal is the power terminal.

The read output circuit 250 includes one or more logic gates, and the logic gate circuit includes one or more of an AND gate, a NOT gate, an OR gate, a NAND gate, or a NOR gate. In the examples of the present disclosure, an example will be illustrated in which the read output circuit 250 is the NAND gate.

In some examples, as shown in connection with FIGS. 5 and 6, the control terminal of the fourth transistor M4 receives a pre-charge signal RD-PRE-N to be turned on, and the power terminal provides the power level VDD to the read node A, so that the read node A is pre-charged to the first level, which may be the power level VDD. The control terminal of the first transistor M1 receives the read enable signal RD-EN to be turned on, and the control terminal of the second transistor M2 receives the trim information in the first state (e.g., at high level) to be turned on. The read node A is coupled to the ground terminal through the first transistors M1 and the second transistors M2 which are turned on, thereby discharging the read node A from the first level to the second level, which may be the ground level VSS. The first input terminal of the NAND gate is coupled to the read node A and receives the second level, and the second input terminal of the NAND gate receives the read output enable signal C_RD_EN. The output terminal of the NAND gate outputs the first read output signal, which is the reading result “1” for the trim information in the first state, for example, RD_OUT=1. User or tester determines whether the reading result “1” is correct. For example, if the reading result “1” is consistent with the preset trim information, the trim information loaded into the trim register 240 is correct. On the contrary, if the reading result “1” is inconsistent with the preset trim information, the trim information loaded into the trim register 240 is incorrect. The preset trim information used in this example and the following may be the trim information obtained after the trim test and written into the memory 200.

In other examples, the read output circuit 250 is configured to: generate a second read output signal based on the read node A being at the first level and the read output enable signal C_RD_EN, wherein the second read output signal is to indicate whether the trim information in the second state is correct.

In some examples, as shown in connection with FIGS. 5 and 6, the control terminal of the fourth transistor M4 receives a pre-charge signal RD_PRE_N to be turned on, and the power terminal provides the power level VDD to the read node A, so that the read node A is pre-charged to the first level, which may be the power level VDD. The control terminal of the first transistor M1 receives a read enable signal RD_EN to be turned on, and the control terminal of the second transistor M2 receives the trim information in the second state (e.g., at low level) to be turned off, thus the read node A remains unchanged at the first level. The first input terminal of the NAND gate receives the first level, the second input terminal of the NAND gate receives the read output enable signal C_RD_EN, and the output terminal of the NAND gate outputs the second read output signal, which is the reading result “0” for the trim information in the second state, for example, RD_OUT=0. User or tester determines whether the reading result “0” is correct. For example, if the reading result “0” is consistent with the preset trim information, the trim information loaded into the trim register 240 is correct. On the contrary, if the reading result “0” is inconsistent with the preset trim information, the trim information loaded into the trim register 240 is incorrect.

In some examples, as shown with reference to FIG. 4, the control logic circuit 220 is coupled to the pre-charge circuit 210, the trim register 240, and the read output circuit 250, respectively. The control logic circuit 220 is configured to: generate the pre-charge signal RD_PRE_N at a first time instant; and generate the read enable signal RD_EN at a second time instant after the first time instant. It may be understood that the fourth transistor M4 in FIG. 5 is turned on before the first transistor M1. In some examples, after pre-charging the read node A to the first level, the control logic circuit 220 may cancel the pre-charge signal RD_PRE_N applied to the control terminal of the fourth transistor M4, causing the fourth transistor M4 to be turned off. After the fourth transistor M4 is turned off, the control logic circuit 220 may apply the read enable signal RD_EN to the control terminal of the first transistor M1, causing the first transistor M1 to be turned on. Of course, the control logic circuit 220 may also generate other control signals or enable signals, such as the read output enable signal C_RD_EN, address signals AD1/AD2/AD3, test control signals TS_SET/TS_RET, an initialization signal POR_SEL, an initialization drive signal POR_SET, and a reset signal RST mentioned in examples of the present disclosure.

In some examples, as shown with reference to FIG. 5, the trim register 240 further includes an address selection circuit 243 comprising at least one third transistor M3, and wherein a first terminal of the third transistor M3 is coupled to the dynamic latch circuit 241, a second terminal of the third transistor M3 is coupled to the first power terminal, and a control terminal of the third transistor M3 is configured to receive an address signal; and the first terminal of the first transistor M1 is coupled to the first power terminal through the third transistor M3. In an example of the present disclosure, the first transistor M1 of the output circuit 244 is coupled to the first power terminal through the third transistor M3 of the address selection circuit 243, which allows the output circuit 244 and the address selection circuit 243 to share the same ground terminal, thereby simplifying the circuit design. The third transistor M3 includes, but not limited to, an NMOS transistor. In the examples of the present disclosure, an example will be illustrated in which the third transistor M3 is an NMOS transistor. As an example, three third transistors M3 are shown in FIG. 5, however, the number of third transistors M3 may be less or more than three, depending on the number of bits of the address signal. There is no special limit on the number of the third transistors M3 in examples of the present disclosure.

In some examples, the address selection circuit 243 further includes a ninth transistor M9 and a fifth transistor M5, wherein a first terminal of the ninth transistor M9 is coupled to the input terminal of the first inverter IV1, a second terminal of the ninth transistor M9 is coupled to the first terminal of the third transistor M3, a first terminal of the fifth transistor M5 is coupled to the output terminal of the first inverter IV1, and a second terminal of the fifth transistor M5 is coupled to a coupling node between the second terminal of the ninth transistor M9 and the first terminal of the third transistor M3. A control terminal of the ninth transistor M9 or a control terminal of the fifth transistor M5 is configured to receive a test control signal. The ninth transistor M9 and the fifth transistor M5 include, but not limited to, NMOS transistors. In the examples of the present disclosure, an example will be illustrated in which both the ninth transistor M9 and the fifth transistor M5 are NMOS transistors. It should be noted that, the address selection circuit 243 may be configured for addressing, thereby enabling the trim register 240 to achieve the above-mentioned test mode function, for example, to latch the trim information into a selected trim register 240 in the test mode.

In some examples, the control terminal of the fifth transistor M5 receives a test control signal “1” (e.g., TS_SET=1) to be turned on. The control terminal of each third transistor M3 receives an address signal “1” (e.g., AD1/AD2/AD3=1) to be turned on. The output terminal of the first inverter IV1 is coupled to the ground terminal through the fifth transistor M5 which is turned on and a plurality of third transistors M3 which are turned on. The output terminal of the first inverter IV1 is discharged to the ground level VSS, thereby latching the trim information “1” into the dynamic latch circuit 241. In this example, the ninth transistor M9 remains in a turned-off state.

In some examples, the control terminal of the ninth transistor M9 receives a test control signal “1” (e.g., TS_RST=1) to be turned on, and the control terminal of each third transistor M3 receives an address signal “1” (e.g., AD1/AD2/AD3=1) to be turned on. The input terminal of the first inverter IV1 is coupled to the ground terminal through the ninth transistor M9 which is turned on and a plurality of third transistors M3 which are turned on. The input terminal of the first inverter IV1 is discharged to the ground level VSS, thereby latching the trim information “0” into the dynamic latch circuit 241. In this example, the fifth transistor M5 remains in a turned-off state.

It should be noted that in the above examples, the control terminal of the ninth transistor M9 or the fifth transistor M5 is firstly set to “1”, and then the control terminal of each third transistor M3 is set to “1”. In other examples, the control terminal of each third transistor M3 may be firstly set to “1”, and then the control terminal of the ninth transistor M9 or the fifth transistor M5 may be set to “1”, for example, there is no special limit on the timing of the test control signal and the address selection signal in examples of the present disclosure.

In some examples, as shown with reference to FIG. 5, the trim register 240 further includes an initialization circuit 242 coupled to the dynamic latch circuit 241, wherein the initialization circuit 242 is configured to initialize the dynamic latch circuit 241 in response to an initialization signal POR_SEL. In an example of the present disclosure, the control logic circuit 220 may generate the initialization signal POR_SEL when the memory 200 is powered on, and send the initialization signal POR_SEL to the initialization circuit 242. The initialization circuit 242 initializes the dynamic latch circuit 241 based on the received initialization signal POR_SEL until the trim information is latched to the dynamic latch circuit 241. In some examples, the control logic circuit 220 may read the trim information stored in the programmable storage circuit 230, and then load the read trim information into the trim register 240. In some examples, the trim information may be latched in the dynamic latch circuit 241.

In some examples, as shown with reference to FIG. 5, the initialization circuit 242 includes a sixth transistor M6, wherein a first terminal of the sixth transistor M6 is coupled to the output terminal of the first inverter IV1, a second terminal of the sixth transistor M6 is coupled to a third power terminal, and a control terminal of the sixth transistor M6 is configured to receive the initialization signal POR_SEL. The sixth transistor M6 includes, but not limited to, an NMOS transistor, and the third power terminal includes, but not limited to, a ground terminal. In the examples of the present disclosure, an example will be illustrated in which the sixth transistor M6 is the NMOS transistor and the third power terminal is the ground terminal. It should be noted that the initialization circuit 242 may be configured to perform initialization operations, thereby enabling the trim register 240 to achieve the above-mentioned data latch function, for example, to latch the trim information into the trim register 240 in the operation mode.

In some examples, the control terminal of the sixth transistor M6 receives an initialization signal “1” (e.g., POR_SEL=1) to be turned on. The output terminal of the first inverter IV1 is coupled to the ground terminal through the sixth transistor M6 which is turned on. The output terminal of the first inverter IV1 is discharged to the ground level VSS, thereby latching the trim information “1” into the dynamic latch circuit 241. Although the specific process of latching the trim information “1” to the dynamic latch circuit 241 during power on initialization is described in this example, in other examples, the trim information “0” may also be latched to the dynamic latch circuit 241 during the power on initialization.

In some examples, as shown with reference FIG. 5, the initialization circuit 242 further includes a seventh transistor M7, wherein a first terminal of the seventh transistor M7 is coupled to the output terminal of the first inverter IV1, a second terminal of the seventh transistor M7 is coupled to the first terminal of the sixth transistor M6, and a control terminal of the seventh transistor M7 is configured to receive an initialization drive signal POR_SET. The seventh transistor M7 includes, but not limited to, an NMOS transistor. In the examples of the present disclosure, an example will be illustrated in which the seventh transistor M7 is the NMOS transistor.

In some examples, the control terminal of the seventh transistor M7 receives the initialization drive signal “1” (e.g., POR_SET=1) to be turned on, thereby driving the initialization circuit 242 to perform initialization operations. Of course, in other examples, the seventh transistor M7 may be omitted, for example, the initialization circuit 242 only includes the sixth transistor M6.

In practical applications, the memory includes a plurality of trim registers. During the power on initialization, the control terminals of the seventh transistors of the plurality of trim registers may be set to a high level “1” to drive the initialization circuit of each trim register to perform initialization operations; the control terminal of the sixth transistor of a selected trim register among the plurality of trim registers may be set to a high level “1” to latch the trim information “1” to the dynamic latch circuit of the selected trim register; and the control terminal of the sixth transistor of an unselected trim register among the plurality of trim registers may be set to a low level “0” to latch the trim information “0” to the dynamic latch circuit of the unselected trim register.

In some examples, as shown with reference to FIG. 5, the trim register 240 further includes a third inverter IV3 coupled to the output terminal of the first inverter IV1. It may be understood that the trim information latched in the dynamic latch circuit 241 is inverted twice and output. Taking the dynamic latch circuit 241 latching the trim information “1” as an example, the trim information “1” becomes “0” after being inverted by the first inverter IV1, and then becomes “1” after being inverted by the third inverter IV3, thereby outputting the trim information “1” latched in the dynamic latch circuit 241.

In some examples, as shown with reference to FIG. 5, the trim register 240 further includes a reset circuit 245 coupled to the dynamic latch circuit 241, wherein the reset circuit 245 is configured to reset the dynamic latch circuit 241 in response to a reset signal RST before initializing the dynamic latch circuit 241. In an example of the present disclosure, the control logic circuit 220 may generate the reset signal RST when the memory 200 is powered on, and send the reset signal RST to the reset circuit 245. The reset circuit 245 resets the dynamic latch circuit 241 based on the received reset signal RST, thereby clearing the information previously latched in the dynamic latch circuit 241 and avoiding affecting the subsequently latched trim information. Here, the control logic circuit 220 may generate the initialization signal POR_SEL after resetting the dynamic latch circuit 241, for example, the initialization signal POR_SEL is generated after the reset signal RST.

In some examples, as shown with reference to FIG. 5, the reset circuit 245 includes an eighth transistor M8, wherein a first terminal of the eighth transistor M8 is coupled to the input terminal of the first inverter IV1, a second terminal of the eighth transistor M8 is coupled to a fourth power terminal, and a control terminal of the eighth transistor M8 is configured to receive the reset signal RST. The eighth transistor M8 includes, but not limited to, an NMOS transistor, the fourth power terminal includes, but not limited to, a ground terminal, and the fourth power terminal and the third power terminal may be the same or different power terminals. In the examples of the present disclosure, an example will be illustrated in which the eighth transistor M8 is the NMOS transistor and the fourth power terminal is the ground terminal.

In some examples, the control terminal of the eighth transistor M8 receives a reset signal “1” (e.g., RST=1) to be turned on. The input terminal of the first inverter IV1 is coupled to the ground terminal through the eighth transistor M8, and the input terminal of the first inverter IV1 is discharged to the ground level VSS, thereby resetting the dynamic latch circuit 241. It should be noted that, during power on reset, the control terminals of the eighth transistors M8 of the plurality of trim registers 240 may be set to the high level “1”, thereby resetting the dynamic latch circuit 241 of each trim register 240, and then the initialization operations are performed.

In some examples, the trim register 240 is further configured to load test trim information from the control logic circuit 220 based on the memory 200 entering a test mode; and latch the test trim information to the dynamic latch circuit 241. In an example of the present disclosure, the trim register 240 may load the test trim information from the control logic circuit 220 when the memory 200 enters the test mode, and latch the loaded test trim information to the dynamic latch circuit 241, wherein the test trim information may be input externally, such as by a tester. It may be understood that in the test mode, the tester inputs test trim information to trim the memory 200 and improve performance of the memory 200. The tester may further optimize the test trim information based on trim results until the memory 200 passes the test, and then save the optimized test trim information to the programmable storage circuit 230. The test trim information finally saved to the programmable storage circuit 230 is the above-mentioned trim information.

In some examples, as shown with reference to FIGS. 4 and 6, the memory 200 further comprises: a plurality of trim registers and a latch circuit 260, wherein the plurality of trim registers are commonly coupled to the read node A, an input terminal of the latch circuit 260 is coupled to the read output circuit 250, and an output terminal of the latch circuit 260 is coupled to a pin 270. The latch circuit 260 is configured to latch read output data in the read output signal RD_OUT, wherein the read output data is to indicate whether the trim information latched in the corresponding trim register is correct.

In an example of the present disclosure, a plurality of trim registers form a trim register group 240G, as shown in FIG. 6. At least one trim register in the trim register group 240G may be selected, and the trim information (e.g., read output data) latched in the selected trim register may be output using the pre-charge circuit 210, the read output circuit 250, and the output circuit 244 of the selected trim register 240. The trim information latched in the selected trim register may be latched in the latch circuit 260 to avoid information loss. In this way, it may be checked that whether the trim information latched in the target trim register is correct, and the target trim register is the selected trim register in the trim register group 240G.

In a memory provided by examples of the present disclosure, the memory includes: a pre-charge circuit configured to: pre-charge a read node based on a pre-charge signal; a trim register coupled to the read node and configured to: output trim information latched in the trim register based on a read enable signal; and select whether to discharge the read node based on the trim information; and a read output circuit coupled to the read node and configured to: generate a read output signal based on a read output enable signal and a level of the read node A, wherein the read output signal is to indicate whether the trim information is correct. In this way, in a first aspect, the readability of the trim information may be achieved, and users or testers may check whether the trim information is correct based on the read output signal RD_OUT; and in a second aspect, the readability of the trim information may be achieved by adding only three transistors with a simple structure (such as a first transistor, a second transistor, and a fourth transistor), which is easy to realize with less modification to the circuit.

Based on the above described memory, a trim register is provided by examples of the present disclosure, comprising: a dynamic latch circuit configured to: latch trim information; and an output circuit coupled to the dynamic latch circuit and configured to: output the trim information latched in the dynamic latch circuit based on a read enable signal; and discharge a read node from a first level to a second level in response to the trim information that is output being in a first state.

In some examples, the output circuit is further configured to: maintain the read node at the first level in response to the trim information that is output being in a second state.

In some examples, the output circuit comprises a first transistor and a second transistor, and wherein a first terminal of the first transistor is coupled to a first power terminal, a second terminal of the first transistor is coupled to a first terminal of the second transistor, and a control terminal of the first transistor is configured to receive the read enable signal; and a second terminal of the second transistor is coupled to the read node, and a control terminal of the second transistor is configured to receive the trim information.

In some examples, the trim register further comprises an address selection circuit comprising at least one third transistor, wherein a first terminal of the third transistor is coupled to the dynamic latch circuit, and a second terminal of the third transistor is coupled to the first power terminal, a control terminal of the third transistor is configured to receive an address signal, and the first terminal of the first transistor is coupled to the first power terminal through the third transistor.

In some examples, the address selection circuit further comprises a fourth transistor and a fifth transistor, wherein a first terminal of the fourth transistor is coupled to an input terminal of a first inverter, a second terminal of the fourth transistor is coupled to the first terminal of the third transistor, a first terminal of the fifth transistor is coupled to an output terminal of the first inverter, and a second terminal of the fifth transistor is coupled to a coupling node between the second terminal of the fourth transistor and the first terminal of the third transistor; and a control terminal of the fourth transistor or a control terminal of the fifth transistor is configured to receive a test control signal.

In some examples, the trim register further comprises an initialization circuit coupled to the dynamic latch circuit and configured to: initialize the dynamic latch circuit in response to an initialization signal.

In some examples, the initialization circuit comprises a sixth transistor, wherein a first terminal of the sixth transistor is coupled to the output terminal of the first inverter, a second terminal of the sixth transistor is coupled to a third power terminal, and a control terminal of the sixth transistor is configured to receive the initialization signal.

In some examples, the initialization circuit further comprises a seventh transistor, wherein a first terminal of the seventh transistor is coupled to the output terminal of the first inverter, a second terminal of the seventh transistor is coupled to the first terminal of the sixth transistor, and a control terminal of the seventh transistor is configured to receive an initialization drive signal.

In some examples, the trim register further comprises a third inverter coupled to the output terminal of the first inverter.

In some examples, the trim register further comprises a reset circuit coupled to the dynamic latch circuit and configured to: reset the dynamic latch circuit in response to a reset signal before initializing the dynamic latch circuit.

In some examples, the reset circuit comprises an eighth transistor, wherein a first terminal of the eighth transistor is coupled to the input terminal of the first inverter, a second terminal of the eighth transistor is coupled to a fourth power terminal, and a control terminal of the eighth transistor is configured to receive the reset signal.

In an example of the present disclosure, the trim register may comprise the trim register 240 in any of the aforementioned examples, and the technical effects achieved by the trim register 240 in the aforementioned examples may also be achieved by the trim register, which will not be described any more here. Regarding the various functions of the trim register 240 in the above examples, the specific examples of each module have been described in detail in the relevant apparatus examples, and will not be described in detail here. It should be emphasized that the trim register may be applied to various chips known in the art.

Based on the above described memory, an operation method for a memory is provided by examples of the present disclosure, which may be applied to any of the memories in the above described examples.

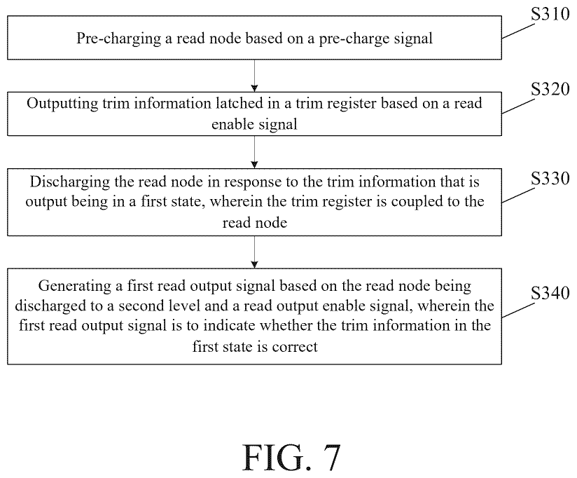

FIG. 7 is a flowchart of an operation method for a memory provided by examples of the present disclosure. The operation method at least includes the following operations:
S310: pre-charging a read node based on a pre-charge signal;
S320: outputting trim information latched in a trim register based on a read enable signal;
S330: discharging the read node in response to the trim information that is output being in a first state, wherein the trim register is coupled to the read node;
S340: generating a first read output signal based on the read node being discharged to a second level and a read output enable signal, wherein the first read output signal is to indicate whether the trim information in the first state is correct.

In some examples, operation S310 includes: pre-charging the read node to a first level based on the pre-charge signal, wherein the first level is greater than the second level; the above operation S330 includes discharging the read node from the first level to the second level in response to the trim information that is output being in the first state.

In some examples, the above operation method further includes maintaining the read node at a first level in response to the trim information that is output being in a second state, wherein the second state is different from the first state, and the first level is greater than the second level.

In some examples, the above operation method further includes generating a second read output signal based on the read node being at the first level and the read output enable signal, wherein the second read output signal is to indicate whether the trim information in the second state is correct.

In some examples, the above operation S310 includes pre-charging the read node to the first level based on the pre-charge signal.

In some examples, the trim register comprises a plurality of trim registers commonly coupled to the read node, and the operation method further comprises: latching read output data in the first read output signal or the second read output signal, wherein the read output data is to indicate whether the trim information latched in the corresponding trim register is correct, respectively.

In examples of the present disclosure, the operation method for the memory may be executed by the control logic circuit in the memory of any of the aforementioned examples, and the technical effects that may be achieved by the memory in the aforementioned examples may also be achieved by the operation method for the memory, which will not be described any more here. Regarding the operation method of the above examples, the specific example of each operation have been described in detail in the relevant apparatus examples, and will not be described in detail here.

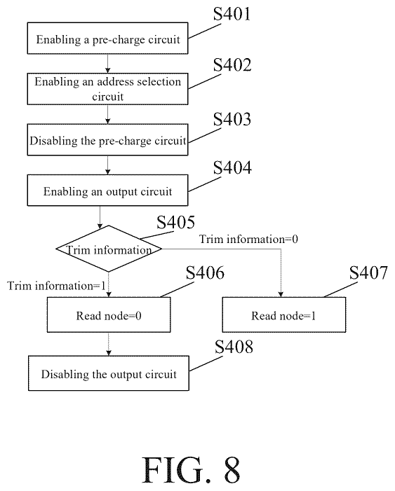

FIG. 8 is a flowchart for reading out trim information provided by examples of the present disclosure. The following will provide an illustration of the operation method for the memory provided by examples of the present disclosure in connection with FIGS. 4, 5, 6, and 8.

As shown with reference to FIG. 8, in operation S401, enabling a pre-charge circuit. In some examples, as shown with reference to FIG. 6, the control logic circuit 220 generates a pre-charge signal RD_PRE_N and sends it to the pre-charge circuit 210. The control terminal of the fourth transistor M4 receives the pre-charge signal RD_PRE_N to be turned on. The power terminal provides a power level VDD to the read node A, thereby pre-charging the read node A to a first level, which may be the power level VDD.

In operation S402, enabling an address selection circuit. In some examples, as shown with reference to FIG. 6, the control logic circuit 220 generates address signals AD1/AD2/AD3 and sends them to the address selection circuit of each trim register in the trim register group 240G, thereby selecting at least one trim register in the trim register group 240G.

In operation S403, disabling the pre-charge circuit. In some examples, as shown with reference to FIG. 6, the control logic circuit 220 cancels the pre-charge signal RD_PRE_N applied to the control terminal of the fourth transistor M4, causing the fourth transistor M4 to be turned off.

In operation S404, enabling an output circuit. In some examples, as shown with reference to FIG. 5, the control logic circuit 220 generates a read enable signal RD_EN and sends it to the output circuit 244. The control terminal of the first transistor M1 receives the read enable signal RD_EN to be turned on.

In operation S405, trim information is in a first state or a second state. If the trim information is in the first state, e.g., the trim information=1, proceed to operation S406; otherwise, if the trim information is in the second state, e.g., trim information=0, proceed to operation S407.

In some examples, as shown with reference to FIG. 5, if the trim information is 1, the output terminal OUT of the third inverter IV3 is 1, the control terminal of the second transistor M2 receives a high level to be turned on, and the read node A is coupled to the ground terminal through the first transistor M1 and second transistor M2 which are turned on, thereby discharging the read node to the ground level VSS, e.g., the read node=0, for example, operation S406.

On the contrary, as shown with reference to FIG. 5, if the trim information is 0, the output terminal OUT of the third inverter IV3 is 0, the control terminal of the second transistor M2 receives a low level to be turned off, and the read node A remains at a high level, e.g., the read node=1, for example, operation S407.

In operation S408, disabling the output circuit. In some examples, after reading out the trim information, the control logic circuit 220 cancels the read enable signal RD_EN applied to the control terminal of the first transistor M1, causing the first transistor M1 to be turned off.

It may be understood that by executing the above operations S401 to S406, and S408, the trim information in the first state latched in the trim register may be read out. Alternatively, by executing operations S401 to S405, S407, and S408, the trim information in the second state latched in the trim register may be read out.

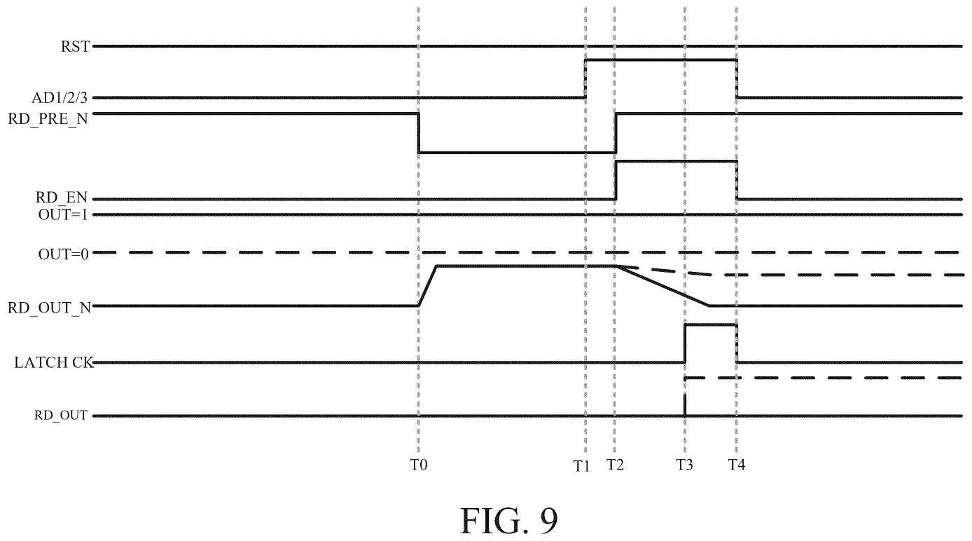

FIG. 9 is an operation timing diagram of a memory provided by examples of the present disclosure. The following will provide an illustration of the operation method for the memory provided by examples of the present disclosure, in connection with FIGS. 4, 5, 6, and 9.

During the time period from T0 to T2, the fourth transistor M4 in the pre-charge circuit 210 is turned on in response to the pre-charge signal “0” (e.g., RD_PRE_N=0), thereby pre-charging the read node A to the power level VDD (e.g., RD_OUT_N=1).

During the time period from T1 to T4, each third transistor M3 of the address selection circuit 243 is turned on in response to the address signal “1” (e.g., AD1/AD2/AD3=1). Here, T1 is between T0 and T2, and T2 is between T1 and T4. It may be understood that the third transistor M3 is turned on after the fourth transistor M4.

During the time period from T2 to T4, the first transistor M1 in the output circuit 244 is turned on in response to the read enable signal “1” (e.g., RD_EN=1), and the first transistor M1 is coupled to the ground terminal through the third transistor M3.

If the trim information is in the first state, the output terminal of the third inverter IV3 outputs a high level (e.g., OUT=1), and the control terminal of the second transistor M2 receives the high level to be turned on. The read node A is discharged from the power level VDD to the ground level VSS through the first transistors M1 and second transistors M2 which are turned on, as shown by the solid line RD_OUT_N in the time period from T2 to T4 in FIG. 9. The read output circuit 250 outputs the first read output signal, as shown by the solid line RD_OUT in FIG. 9.

If the trim information is in the second state, the output terminal of the third inverter IV3 outputs a low level (e.g., OUT=0), the control terminal of the second transistor M2 receives the low level to be turned off, and the read node A remains unchanged at a high level, as shown by the dashed line RD_OUT_N in the time period from T2 to T4 in FIG. 9. The read output circuit 250 outputs a second read output signal, as shown by the dashed lined RD_OUT in FIG. 9.

It should be noted that in practical applications, even if the control terminal of the second transistor M2 receives a low level to be turned off, the level of the read node A may be slightly decreased due to the presence of transistor leakage current, for example, slightly lower than the power level VDD, as shown in FIG. 9, but the impact on the actual read-out result is small.

During the time period from T3 to T4, the latch circuit 260 samples the first read output signal based on the rising edge of a latch clock signal LATCH CK, thereby latching the read output data in the first read output signal into the latch circuit 260. The read output data latched in the latch circuit 260 may be output through the pin 270, so that users or testers can check whether the trim information is correct. Here, T3 is between T2 and T4.

Based on the aforementioned memories, a memory system is provided by examples of the present disclosure, comprising: one or more of the aforementioned memories; a memory controller coupled to the memories and configured to control the memories.

Based on the aforementioned memory system, an electronic device is provided by examples of the present disclosure, comprising: the aforementioned memory system.

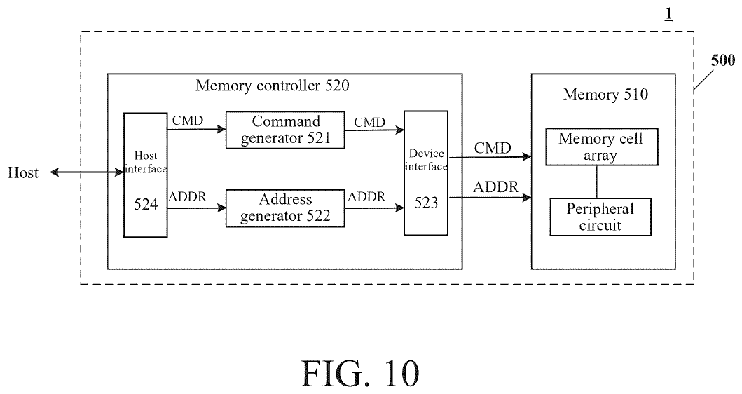

FIG. 10 is a schematic diagram of an electronic device provided by examples of the present disclosure. The following will provide an illustration of the electronic device and the memory system provided by examples of the present disclosure, in connection with FIG. 10. The electronic device 1 may comprise a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device with a storage therein.

As shown in FIG. 10, the electronic device 1 may include a host and a memory system 500, wherein the memory system 500 comprises one or more memories 510 and a memory controller 520. The host may be the processor of electronic device 1, for example, a Central Processing Unit (CPU) or a System on Chip (SoC), such as an Application Processor (AP). The host may be configured to send or receive data to or from the memory 510. The memory controller 520 is coupled to the memory 510 and the host, and is configured to control the memory 510. The memory controller 520 may manage the data stored in the memory 510 and communicate with the host. The memory 510 may be similar to the memory 200 in FIG. 4.

The memory controller 520 may be configured to control the operations of the memory 510, such as read, erase, write, and refresh operations. In some examples, the memory controller 520 is also configured to process error correction codes (ECC) for data read from or written to the memory 510. The memory controller 520 may also perform any other suitable functions, such as formatting the memory 510.

In some examples, the memory controller 520 and one or more memories 510 may be integrated into various types of storage devices. For example, the memory controller 520 may be integrated into the north bridge of a computer motherboard or directly integrated into the CPU of the computer, and a plurality of memories 510 may be integrated into a memory bar. For example, the memory system 500 may be implemented and packaged into different types of end electronic products.

The memory controller 520 may send or receive data to or from the host, and may send a command (CMD) and an address (ADDR) to the memory 510. The memory controller 520 may include a command generator 521, an address generator 522, a device interface 523, and a host interface 524. The host interface 524 may receive the command CMD and address ADDR from the host. The command generator 521 may generate an access command, a refresh command, etc. by decoding the command CMD received from the host, and may provide the access command and refresh command to the memory 510 through the device interface 523. The access command may be a signal that indicates the memory 510 to write or read data by accessing the row of the memory cell array corresponding to the address ADDR. The refresh command may be a signal that indicates the memory 510 to read out and rewrite data by accessing the row of the memory cell array corresponding to the refresh address ADDR.

The address generator 522 in the memory controller 520 may generate a row and column address to be accessed in the memory cell array by decoding the address ADDR received from the host interface 524. In addition, the memory 510 may generate an address of the memory bank to be accessed when the memory cell array includes a plurality of memory banks.

In addition, the memory controller 520 may control memory operations such as write and read operations by providing various signals to the memory 510 via the device interface 523. For example, the memory controller 520 may provide a write command to the memory 510. The write command is to indicate the memory 510 to perform a write operation to store data in the memory 510.

The features disclosed in the several apparatus examples provided by the present disclosure may be combined arbitrarily without conflict to obtain a new apparatus example.

The methods disclosed in the several method examples provided by the present disclosure may be combined arbitrarily without conflict to obtain a new method example.

It should be understood that the term “one example” or “an example” mentioned throughout the specification means that specific features, structures, or characteristics related to the examples are included in at least one example of the present disclosure. Therefore, the phrases “in one example” or “in an example” that appear throughout the specification may not refer to the same example. In addition, these specific features, structures, or characteristics may be combined in any suitable manner in one or more examples. It should be understood that in various examples of the present disclosure, the order of the sequence numbers of the above described processes does not mean the order of execution. The execution order of each process should be determined by its function and internal logic, and should not constitute any limitation on the implementation process of examples of the present disclosure. The sequence numbers of the above described examples of the present disclosure are just for illustration and do not represent the advantages or disadvantages of the examples.

It should be noted that the terms “including”, “comprising”, or any other variation thereof herein are intended to encompass non-exclusive inclusion, such that a process, method, article, or apparatus that includes a series of elements not only includes those elements, but also includes other elements not explicitly listed, or also includes elements inherent to such process, method, article, or apparatus. Without further limitations, the element limited by the statement “including one . . . ” does not exclude the existence of other identical elements in the process, method, article, or apparatus that includes the element.

The above are only examples of the present disclosure, but the scope of the present disclosure is not limited thereto. Within the technical scope disclosed in the present disclosure, any skilled in the art may easily think of variations or replacements which should be included in the scope of the present disclosure.

What is claimed is:

1. A memory, comprising:
a pre-charge circuit configured to:
pre-charge a read node based on a pre-charge signal;
a trim register coupled to the read node and configured to:
output trim information latched in the trim register based on a read enable signal; and
select whether to discharge the read node based on the trim information; and
a read output circuit coupled to the read node and configured to:
generate a read output signal based on a read output enable signal and a level of the read node, wherein the read output signal is to indicate whether the trim information is correct.

2. The memory of claim 1, wherein the trim register comprises:
a dynamic latch circuit configured to:
latch the trim information; and
an output circuit coupled to the dynamic latch circuit and configured to:
output the trim information latched in the dynamic latch circuit based on the read enable signal; and
discharge the read node in response to the trim information that is output being in a first state.

3. The memory of claim 2, wherein,
the pre-charge circuit is configured to:
pre-charge the read node to a first level based on the pre-charge signal;
the output circuit is configured to:
discharge the read node from the first level to a second level based on the trim information that is output being in the first state; and
the read output circuit is configured to:
generate a first read output signal based on the read node being at the second level and the read output enable signal, wherein the first read output signal is to indicate whether the trim information in the first state is correct.

4. The memory of claim 2, wherein the output circuit is further configured to:
maintain a level of the read node in response to the trim information that is output being in a second state, wherein the second state is different from the first state.

5. The memory of claim 4, wherein,
the pre-charge circuit is configured to:
pre-charge the read node to a first level based on the pre-charge signal; and
the read output circuit is configured to:
generate a second read output signal based on the read node being at the first level and the read output enable signal, wherein the second read output signal is to indicate whether the trim information in the second state is correct.

6. The memory of claim 2, wherein:
the output circuit comprises a first transistor and a second transistor;
a first terminal of the first transistor is coupled to a first power terminal, a second terminal of the first transistor is coupled to a first terminal of the second transistor, and a control terminal of the first transistor is configured to receive the read enable signal; and
a second terminal of the second transistor is coupled to the read node, and a control terminal of the second transistor is configured to receive the trim information.

7. The memory of claim 6, wherein:
the trim register further comprises an address selection circuit comprising at least one third transistor;
a first terminal of the third transistor is coupled to the dynamic latch circuit, a second terminal of the third transistor is coupled to the first power terminal, and a control terminal of the third transistor is configured to receive an address signal; and
the first terminal of the first transistor is coupled to the first power terminal through the third transistor.

8. The memory of claim 1, wherein the trim register comprises a plurality of trim registers commonly coupled to the read node, and the memory further comprises:
a latch circuit, wherein an input terminal of the latch circuit is coupled to the read output circuit, an output terminal of the latch circuit is coupled to a pin, and the latch circuit is configured to:
latch read output data in the read output signal, wherein the read output data is to indicate whether the trim information latched in the corresponding trim register is correct.

9. The memory of claim 1, further comprising:
a control logic circuit coupled to the pre-charge circuit, the trim register, and the read output circuit respectively and configured to:
generate the pre-charge signal at a first time instant; and
generate the read enable signal at a second time instant after the first time instant.

10. The memory of claim 1, wherein the pre-charge circuit comprises a fourth transistor, and wherein a first terminal of the fourth transistor is coupled to the read node, a second terminal of the fourth transistor is coupled to a second power terminal, and a control terminal of the fourth transistor is configured to receive the pre-charge signal.

11. An operation method of a memory, comprising:
pre-charging a read node based on a pre-charge signal;
outputting trim information latched in a trim register based on a read enable signal;
discharging the read node in response to the trim information that is output being in a first state, wherein the trim register is coupled to the read node; and
generating a first read output signal based on the read node being discharged to a second level and a read output enable signal, wherein the first read output signal is to indicate whether the trim information in the first state is correct.

12. The operation method of claim 11, wherein,
pre-charging a read node based on a pre-charge signal comprises:
pre-charging the read node to a first level based on the pre-charge signal, wherein the first level is greater than the second level; and
discharging the read node in response to the trim information that is output being in a first state comprises:
discharging the read node from the first level to the second level in response to the trim information that is output being in the first state.

13. The operation method of claim 11, further comprising:
maintaining the read node at a first level in response to the trim information that is output being in a second state, wherein the second state is different from the first state, and the first level is greater than the second level.

14. The operation method of claim 13, further comprising:
generating a second read output signal based on the read node being at the first level and the read output enable signal, wherein the second read output signal is to indicate whether the trim information in the second state is correct.

15. The operation method of claim 14, wherein pre-charging a read node based on a pre-charge signal comprises:
pre-charging the read node to the first level based on the pre-charge signal.

16. The operation method of claim 14, wherein the trim register comprises a plurality of trim registers commonly coupled to the read node, and the operation method further comprises:
latching read output data in the first read output signal or the second read output signal, wherein the read output data is to indicate whether the trim information latched in the corresponding trim register is correct, respectively.

17. A trim register, comprising:
a dynamic latch circuit configured to:
latch trim information; and
an output circuit coupled to the dynamic latch circuit and configured to:
output the trim information latched in the dynamic latch circuit based on a read enable signal; and
discharge a read node from a first level to a second level in response to the trim information that is output being in a first state.

18. The trim register of claim 17, wherein the output circuit is further configured to:
maintain the read node at the first level in response to the trim information that is output being in a second state.

19. The trim register of claim 17, wherein:
the output circuit comprises a first transistor and a second transistor;
a first terminal of the first transistor is coupled to a first power terminal, a second terminal of the first transistor is coupled to a first terminal of the second transistor, and a control terminal of the first transistor is configured to receive the read enable signal; and
a second terminal of the second transistor is coupled to the read node, and a control terminal of the second transistor is configured to receive the trim information.

20. The trim register of claim 19, further comprising:
an address selection circuit comprising at least one third transistor, wherein a first terminal of the third transistor is coupled to the dynamic latch circuit, and a second terminal of the third transistor is coupled to the first power terminal, a control terminal of the third transistor is configured to receive an address signal, and the first terminal of the first transistor is coupled to the first power terminal through the third transistor.
